(19) United States
(12) Patent Application Publication
(10) Pub. No.: US 2008/0121954 A1
(43) Pub. Date: May 29, 2008

(54) FERROELECTRIC STORAGE DEVICE AND METHOD OF FABRICATING THE SAME

(76) Inventor: Susumu SHUTO, Yokohama-shi (JP)

Correspondence Address: OBLON, SPIVAK, MCCLELLAND MAIER & NEUSTADT, P.C., 1940 DUKE STREET, ALEXANDRIA, VA, 22314, US

(21) Appl. No.: 11/563,084

(22) Filed: Nov. 24, 2006

(30) Foreign Application Priority Data
Aug. 18, 2006 (JP) 2006-223228

(51) Int. Cl. H01L 29/78; H01L 21/02

(52) U.S. Cl. 257/295; 438/3; 257/E21.002; 257/E29.256

(57) ABSTRACT

A ferroelectric layer is formed on a semiconductor substrate, a first hard mask layer is formed on the ferroelectric layer, and a second hard mask layer is formed on the first hard mask layer. A plurality of parallel isolation trenches are formed by etching the second hard mask layer, first hard mask layer, and ferroelectric layer in a direction perpendicular to the major surface of the substrate. Electrode layers are formed on the sidewalls of the ferroelectric layer which face the trenches and on the second hard mask layer.

### CROSS-REFERENCE TO RELATED APPLICATIONS

This application is based upon and claims the benefit of priority from prior Japanese Patent Application No. 2006-223228, field Aug. 18, 2006, the entire contents of which are incorporated herein by reference.

### BACKGROUND OF THE INVENTION

1. Field of the Invention

The present invention relates to a data storage device and a method of fabricating the same and, more particularly, to a ferroelectric storage device which stores data in a ferroelectric capacitor and a method of fabricating the same.

2. Description of the Related Art

A TC (Transistor Capacitor) parallel ferroelectric memory is proposed as an FeRAM which can increase the density and processing speed (examples are Jpn. Pat. Appln. KOKAI Publication Nos. 2002-299572 and 10-255483, U.S. Pat. No. 5,903,492, and N. Nagel et al., “New Highly Scalable 3 Dimensional Chain FeRAM Cell with Vertical Capacitor”, IEEE Symposium on VLSI technology 2004, pp. 146). In the TC parallel ferroelectric memory, an array of three-dimensional capacitors is formed in parallel with a transistor array.

Photolithography and RIE (Reactive Ion Etching) are used to fabricate the three-dimensional capacitor, e.g., to process PZT (PbZrTiO₃: lead zirconate titanate) as one material of the capacitor. After PZT is processed, an electrode material is deposited on the entire surface of PZT including the PZT sidewalls in contact with electrodes of the capacitor.

In this method, the electrode material deposited to continuously cover a plurality of cells must function as an independent electrode after that. Therefore, the method further requires a step such as CMP (Chemical Mechanical Polishing) in order to separate the deposited electrode material in the center of each cell. However, CMP for a noble metal such as platinum (Pt) used as the electrode material has not been technically established yet.

If separation by CMP is difficult, therefore, a means for separating the electrode layer by using, e.g., lithography and etching is performed. In this case, the electrode material must be removed by a width smaller than the width between the PZT sidewalls which is the width of a parallel-plate capacitor. Accordingly, the accuracy of photolithography in this portion determines the size of a memory cell, and this makes micropatterning difficult.

### BRIEF SUMMARY OF THE INVENTION

A ferroelectric storage device fabrication method according to the first aspect of the present invention comprises forming a ferroelectric layer on a semiconductor substrate, forming a first hard mask layer on the ferroelectric layer, forming a second hard mask layer on the first hard mask layer, forming a plurality of parallel isolation trenches by etching the second hard mask layer, the first hard mask layer, and the ferroelectric layer in a direction perpendicular to a major surface of the substrate, and forming electrode layers on sidewalls of the ferroelectric layer which face the trenches and an electrode layer on the second hard mask layer.

A ferroelectric storage device according to the second aspect of the present invention comprises a source region and a drain region formed in a semiconductor substrate, a gate electrode formed on the substrate, a ferroelectric layer formed on the gate electrode, a first electrode portion formed on a sidewall of the ferroelectric layer which faces the source region, a second electrode portion formed on a sidewall of the ferroelectric layer which faces the drain region, and opposing the first electrode portion, a third electrode portion which connects the first electrode portion to the source region, a fourth electrode potion which connects the second electrode portion to the drain region, a first hard mask layer formed on the ferroelectric layer and receding from the sidewalls of the ferroelectric layer, a second hard mask layer formed on the first hard mask layer, and a cap electrode layer formed on the second hard mask layer and electrically isolated from the first electrode portion and the second electrode portion.

### BRIEF DESCRIPTION OF THE SEVERAL VIEWS OF THE DRAWING

FIG. 1 is a sectional view of a ferroelectric storage device according to each of the first and second embodiments;

FIG. 2 is a sectional view showing a ferroelectric storage device fabrication method according to each of the first to third embodiments;

FIG. 3 is a sectional view following FIG. 2 and showing the ferroelectric storage device fabrication method according to the first embodiment;

FIG. 4 is a sectional view following FIG. 3 and showing the ferroelectric storage device fabrication method according to the first embodiment;

FIG. 5 is a sectional view following FIG. 4 and showing the ferroelectric storage device fabrication method according to the first embodiment;

FIG. 6 is a sectional view showing a conventional ferroelectric storage device fabrication method;

FIG. 7 is a sectional view following FIG. 6 and showing the conventional ferroelectric storage device fabrication method;

FIG. 8 is a sectional view showing the conventional ferroelectric storage device fabrication method;

FIG. 9 is a sectional view following FIG. 7 and showing the conventional ferroelectric storage device fabrication method;

FIG. 10 is a sectional view following FIG. 9 and showing the conventional ferroelectric storage device fabrication method;

FIG. 11 is a sectional view following FIG. 9 and showing the conventional ferroelectric storage device fabrication method;

FIG. 12 is a sectional view following FIG. 2 and showing the ferroelectric storage device fabrication method according to the second embodiment;

FIG. 13 is a sectional view following FIG. 12 and showing the ferroelectric storage device fabrication method according to the second embodiment;

FIG. 14 is a sectional view following FIG. 13 and showing the ferroelectric storage device fabrication method according to the second embodiment;

FIG. 15 is a sectional view following FIG. 14 and showing the ferroelectric storage device fabrication method according to the second embodiment;

FIG. 16 is a sectional view following FIG. 2 and showing the ferroelectric storage device fabrication method according to the third embodiment;

FIG. 17 is a sectional view following FIG. 16 and showing the ferroelectric storage device fabrication method according to the third embodiment;

FIG. 18 is a sectional view following FIG. 17 and showing the ferroelectric storage device fabrication method according to the third embodiment; and

FIG. 19 is a sectional view of the ferroelectric storage device according to the third embodiment.

### DETAILED DESCRIPTION OF THE INVENTION

Embodiments of the present invention will be explained in detail below with reference to the accompanying drawing. Note that in the following explanation, the same reference numerals denote elements having the same functions and arrangements.

### First Embodiment

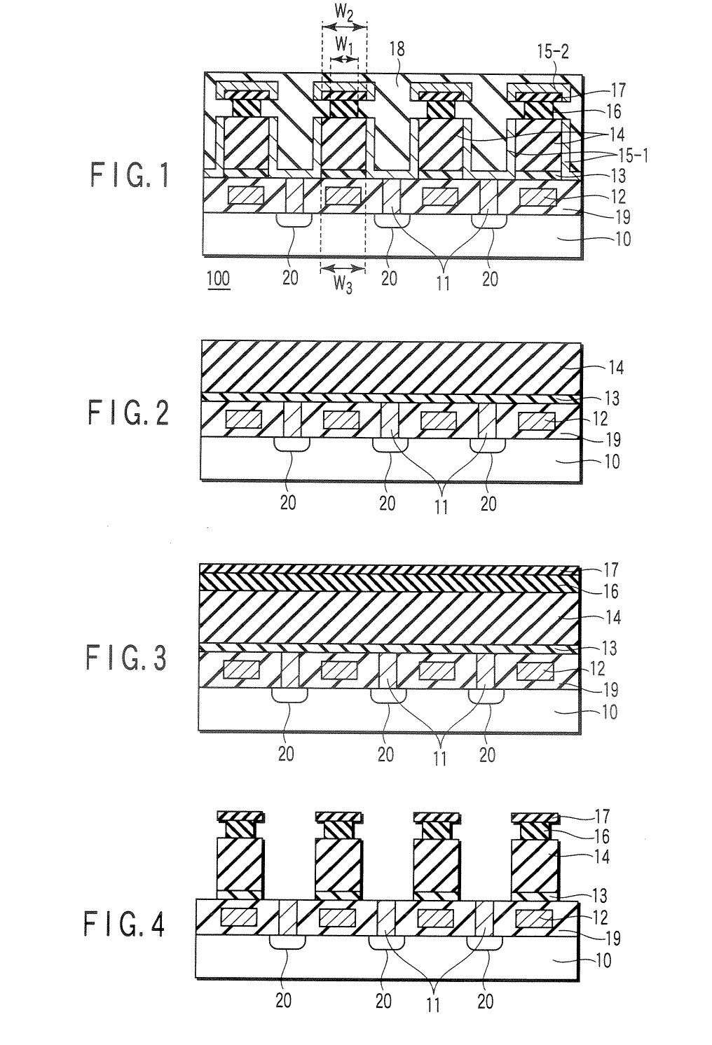

FIG. 1 is a sectional view of a ferroelectric storage device according to the first embodiment of the present invention.

A TC parallel ferroelectric memory 100 shown in FIG. 1 comprises a silicon (Si) substrate 10, contact holes 11, gate electrodes 12, alumina (Al₂O₃) films 13, PZT 14 (ferroelectric layers), electrode layers 15-1, cap electrode layers 15-2, first hard masks 16, second hard masks 17, and interlayer dielectrics (ILDs) 18 and 19.

The contact hole 11 connects to a source/drain region 20 of a transistor in each memory cell. The source/drain region 20 functions as a source region for one of adjacent transistors and as a drain region for the other. The gate electrode 12 controls the channel of each transistor. A capacitor including the electrode layers 15-1 and ferroelectric layer 14 (PZT) (each will be explained below) is formed on each transistor.

The PZT 14 is a ferroelectric layer which forms a ferroelectric parallel-plate capacitor serving as a memory cell. The electrode layers 15-1 are capacitor electrodes which form opposing parallel-plate electrodes sandwiching the PZT 14. The electrode layers 15-1 are made of a noble metal electrode material such as platinum or iridium.

One of the pair of electrode layers 15-1 is made up of a first electrode portion formed on one sidewall of the PZT 14, and a third electrode portion formed on the interlayer dielectric 19 so as to connect the first electrode portion to the contact hole 11 connecting to the source region 20.

The other one of the pair of electrode layers 15-1 is made up of a second electrode portion formed on the other sidewall of the PZT 14 so as to oppose the first electrode portion, and a fourth electrode portion formed on the interlayer dielectric 19 so as to connect the second electrode portion to the contact hole 11 connecting to the drain region 20.

The first hard mask 16 is formed on the PZT 14, and the second hard mask 17 is formed on the first hard mask 16. A width W₁ in the channel length direction of the first hard mask 16 is smaller than a width W₃ in the channel length direction of the PZT 14 (i.e., the width of the parallel-plate capacitor) and a width W₂ in the channel length direction of the second hard mask 17.

Although the cap electrode layer 15-2 is made of the same electrode material as the electrode layers 15-1, it is in contact with only the second hard mask 17 and electrically insulated as it is separated from the electrode layer 15-1. That is, the electrode material is generally deposited on the entire surface of a cell but is not formed on the two sidewalls of the first hard mask 16. This electrically separates the opposing capacitor electrodes.

A method of fabricating the ferroelectric storage device according to this embodiment will be explained below reference to sectional views shown in FIGS. 2 to 5.

As shown in FIG. 2, an interlayer dielectric 19 is deposited on a silicon substrate 10 having source/drain regions 20, and gate electrodes 12 made of, e.g., polysilicon are formed on the interlayer dielectric 19. After that, an interlayer dielectric 19 is further deposited to cover the gate electrodes 12, and the surface of the interlayer dielectric 19 is planarized.

A stacked film (not shown) of, e.g., a silicon nitride film (e.g., SiN) and silicon oxide film (SiO₂) is deposited on the planarized interlayer dielectric 19. In ferroelectric capacitor formation steps to be performed later, annealing is performed several times in an oxygen ambient. During this annealing, the silicon nitride film or the like prevents oxygen from reaching the gate electrodes 12 and oxidizing the gate material.

Then, contact holes 11 are formed for transistors in memory cells. More specifically, after the positions and shape of the holes are determined by photolithography, the silicon oxide film, silicon nitride film, and interlayer dielectric 19 are removed by reactive ion etching.

After that, a barrier metal layer (not shown) is deposited by sputtering or CVD (Chemical Vapor Deposition), and a refractory metal such as tungsten is deposited and buried in the contact holes 11 by CVD. The tungsten and barrier metal in portions except for the contact holes 11 are then removed by CMP or the like to complete the buried contact holes 11. The contact holes 11 are in contact with the source/drain regions 20.

Furthermore, a thin alumina film 13 is deposited on the entire surface. This layer helps improve the crystallinity of PZT 14 which is deposited and crystallized on the alumina film 13 after that. PZT 14 is then deposited by sputtering or CVD. The deposited film thickness of the PZT 14 is, e.g., 300 nm.

The area of a ferroelectric parallel-plate capacitor to be formed later is obtained by multiplying this deposited film thickness by the depth of the capacitor in the direction perpendicular to the drawing surface. One method of increasing this area is to increase the deposited film thickness. If the PZT 14 is not crystallized during deposition, annealing is subsequently performed to crystallize the PZT 14. The steps up to this point form the structure shown in the sectional view of FIG. 2.

Then, as shown in FIG. 3, a first hard mask 16 and second hard mask 17 which function as mask materials when the PZT 14 is processed by reactive ion etching are sequentially deposited.

In this step, the material of the first hard mask 16 as a lower mask material is selected so that reactive ion etching to be performed later progresses more in the first hard mask 16 than in the PZT 14 and second hard mask 17 in the lateral direction, i.e., in the direction parallel to the major surface of the silicon substrate 10 and perpendicular to the electrode surface of the parallel-plate capacitor. That is, a material having an etching rate higher than those of the PZT 14 and second hard mask 17 is selected as the first hard mask 16.

The first hard mask 16 and second hard mask 17 are then processed by photolithography and reactive ion etching using a resist, and used as masks to process the PZT 14 into a plurality of thin plates. That is, etching is performed in the direction perpendicular to the major surface of the substrate 10 to form a plurality of parallel isolation trenches, thereby forming a plurality of parallel cell regions between these trenches.

When the material having a high etching rate is used as the first hard mask 16 as described above, as shown in FIG. 4, the first hard mask 16 is side-etched such that the width in the lateral direction is smaller than those of the PZT 14 and second hard mask 17.

After that, as shown in FIG. 5, an electrode material made of a noble metal such as platinum or iridium is deposited by CVD or the like. This electrode material is deposited to have a sufficient thickness even on the sidewalls of the PZT 14. Since, the second hard mask 17 protrudes, i.e., overhangs from the first hard mask 16, the electrode material is deposited on the sidewalls and upper surface of the second hard mask 17, but does not cover the sidewalls of the first hard mask 16. That is, the electrode material is discontinuous, failing to achieve so-called step coverage.

This separates the formed electrode layer as shown in FIG. 5. More specifically, the electrode layer is automatically separated into electrode layers 15-1 which sandwich the PZT 14 to form electrodes of a parallel-plate capacitor, and a cap electrode layer 15-2 electrically insulated as it is separated from the electrode layers 15-1.

Finally, a TC parallel ferroelectric memory as shown in FIG. 1 is formed by depositing an interlayer dielectric 18 such as SiO₂ so as to cover the entire surface.

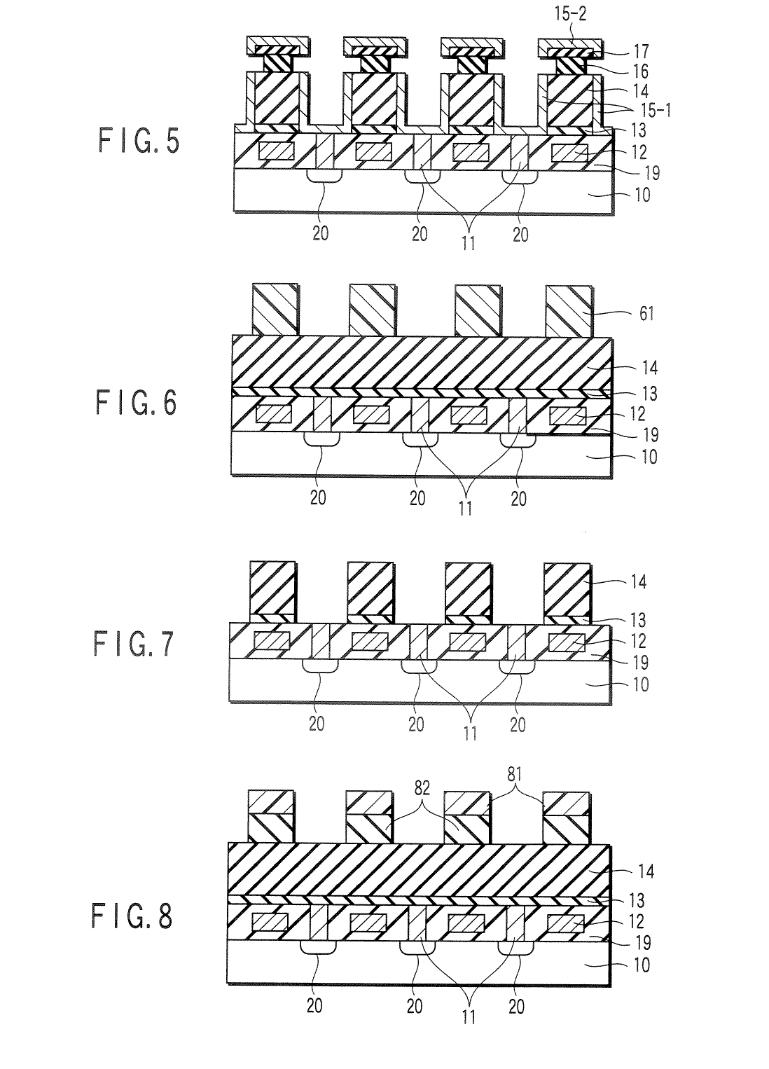

To compare the ferroelectric storage device fabrication method according to this embodiment with prior art, a fabrication method which uses prior art to process PZT and separate an electrode layer will be explained below with reference to FIGS. 6 to 11.

In the state shown in FIG. 2 in which a crystallized PZT layer is formed, the entire upper surface of the PZT 14 is coated with a photoresist 61. FIG. 6 shows a state in which the photoresist 61 is left behind in portions which serve as dielectrics of parallel-plate capacitors. Subsequently, as shown in FIG. 7, the PZT 14 is processed into thin plates by reactive ion etching.

Unfortunately, this method is impractical because a thick photoresist is necessary to process the PZT 14. As shown in FIG. 8, therefore, a general method is to once transfer the pattern of a photoresist 81 to a hard mask 82 having a high selectivity, and then process the PZT 14 by reactive ion etching.

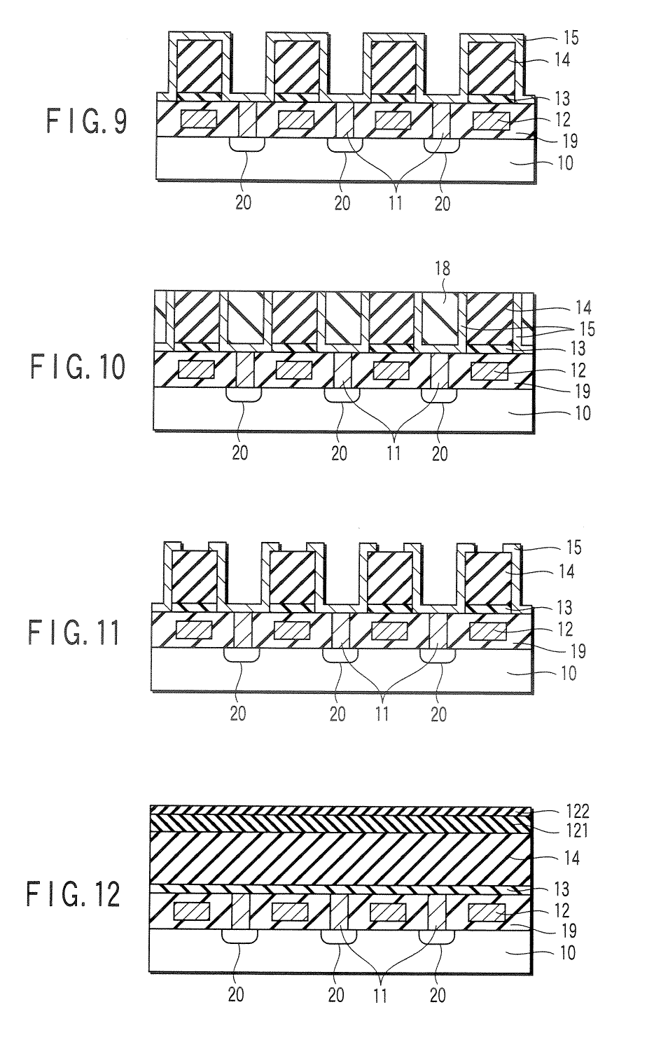

Then, as shown in FIG. 9, an electrode layer 15 made of a noble metal such as platinum or iridium is deposited along the surface shape of the processed PZT 14. The electrode layer 15 is deposited to have a sufficient thickness even on the sidewalls of the PZT 14.

After that, an interlayer dielectric 18 such as SiO₂ is deposited to fill trenches shown in FIG. 9. Etching for planarization is then performed by, e.g., CMP. This separates the electrode layer 15 by removing the top portions of the electrode layer 15 together with the interlayer dielectric 18. Consequently, as shown in FIG. 10, the separated electrode layers 15 function as one parallel-plate capacitor sandwiching the PZT 14 for each transistor.

Unfortunately, CMP to a noble metal such as platinum or iridium used as the electrode layer 15 is a difficult method which has not been technically established yet. As another method, therefore, it is possible to separate the electrode layer 15 by using, e.g., lithography and etching.

In this case, as shown in FIG. 11, the top portions of the electrode layer 15 must be removed by a width smaller than the width between the sidewalls of the PZT 14 which is the width of the parallel-plate capacitor. Accordingly, the accuracy of lithography in this portion determines the size of a memory cell, and this makes micropatterning of cells difficult.

As described above, it is technically difficult to process PZT and separate the electrode layer by using the prior art, and this makes micropatterning of cells difficult. However, the ferroelectric storage device fabrication method according to this embodiment can automatically separate the electrode layer when depositing it, by depositing two types of selected hard masks on PZT. Since this omits the electrode layer separation step, the fabrication process can be simplified.

In addition, in the ferroelectric storage device according to this embodiment, the accuracy of lithography does not limit the size of a memory cell unlike when the electrode layer is separated by using lithography and etching. Accordingly, memory cells can be micropatterned.

### Second Embodiment

A ferroelectric storage device fabrication method according to the second embodiment of the present invention will be explained below with reference to sectional views shown in FIGS. 12 to 15.

In this embodiment, steps up to FIG. 2 are the same as in the first embodiment.

As shown in FIG. 12, a first hard mask 121 and second hard mask 122 as two types of mask materials for reactive ion etching for processing PZT 14 are sequentially deposited on the PZT 14 shown in FIG. 2. This step is also the same as in the first embodiment except for a mask material selection method.

In this step, the mask materials are selected so that the etching rate of the first hard mask 121 is higher than those of the second hard mask 122 and PZT 14 in an etching step after a step of forming isolation trenches performed later.

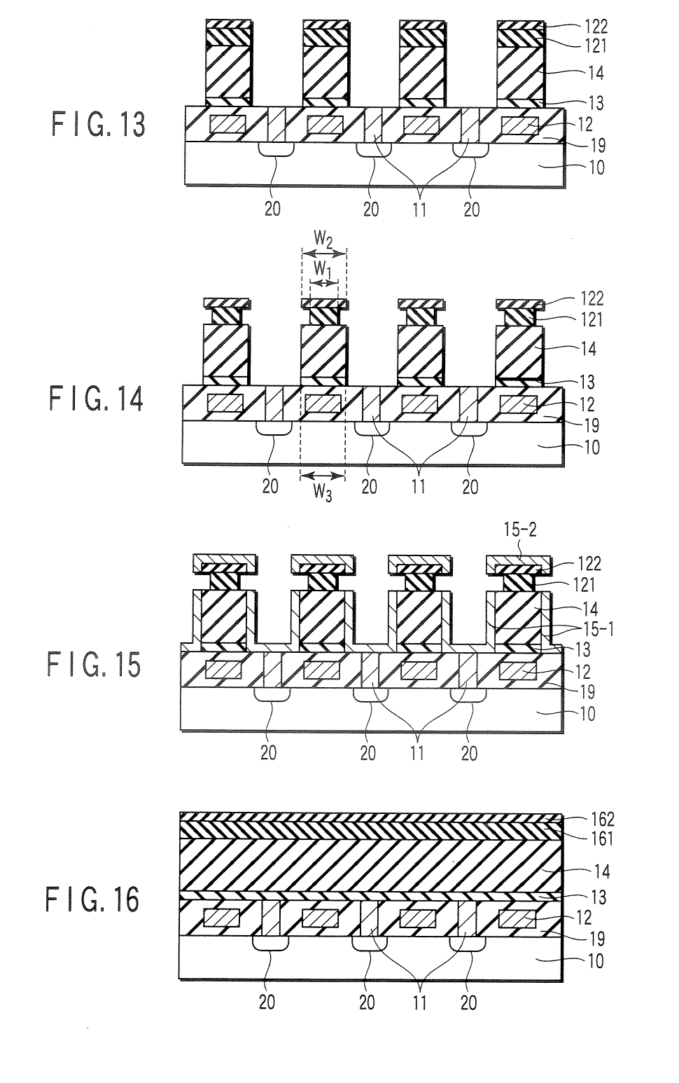

Then, as shown in FIG. 13, a plurality of parallel isolation trenches are formed in the first hard mask 121 and second hard mask 122 by photolithography and reactive ion etching. In addition, the remaining first hard mask 121 and second hard mask 122 are used as masks to etch the PZT 14 to form a plurality of parallel cell regions.

In this state, as shown in FIG. 13, the PZT 14 and the first hard mask 121 and second hard mask 122 as two types of mask materials are processed so as to have, e.g., substantially the same width.

After that, as shown in FIG. 14, the first hard mask 121 is isotropically etched by CDE (Chemical Dry etching) or wet etching. In this case, when the two types of mask materials are selected as described above, the first hard mask 121 is etched to be narrower in the lateral direction than the second hard mask 122.

That is, the first hard mask 121 is side-etched such that a width W₁ in the lateral direction of the first hard mask 121, i.e., in the direction perpendicular to the electrode surface of a parallel-plate capacitor is smaller than a width W₂ of the second hard mask 122 and a width W₃ of the PZT 14.

This embodiment is advantageous in that a best possible choice can be made from various materials of the mask because the step of forming cell regions shown in FIG. 13 and the side-etching step shown in FIG. 14 are different steps.

After that, as shown in FIG. 15, a noble metal electrode material such as platinum and iridium is deposited by using, e.g., CVD. This electrode material is deposited by a method which well deposits the material even on the sidewalls of the PZT 14. As in the first embodiment, the second hard mask 122 protrudes, i.e., overhangs from the first hard mask 121, so the electrode material is discontinuously deposited, failing to achieve so-called step coverage.

This separates the formed electrode layer as shown in FIG. 15. More specifically, the electrode layer is automatically separated into electrode layers 15-1 which sandwich the PZT 14 to form electrodes of a parallel-plate capacitor, and a cap electrode layer 15-2 electrically insulated as it is separated from the electrode layers 15-1.

Finally, an interlayer dielectric 18 such as SiO₂ is deposited to cover the entire surface, thereby forming a TC parallel ferroelectric memory as shown in FIG. 1 in the same manner as in the first embodiment.

As described above, the ferroelectric storage device fabrication method according to this embodiment also automatically separates the electrode layer. Since this omits the step for separation, the fabrication process can be simplified compared to prior art.

In addition, memory cells can be micropatterned in the ferroelectric storage device according to this embodiment as well, when compared to a device in which the electrode layer is separated by using lithography and etching.

### Third Embodiment

A ferroelectric storage device fabrication method according to the third embodiment of the present invention will be described below with reference to sectional views shown in FIGS. 16 to 19.

In this embodiment, steps up to FIG. 2 are the same as in the first and second embodiments.

As shown in FIG. 16, a first hard mask 161 and second hard mask 162 as two types of mask materials for reactive ion etching for processing PZT 14 are sequentially deposited on the PZT 14 shown in FIG. 2. This step is also the same as in the first and second embodiments except for a mask material selection method.

In this step, mask materials substantially different in electrode material deposition rate are selected so that an electrode material is deposited on the surface of the second hard mask 162 but is not deposited on the surface of the first hard mask 161 at all in an electrode material deposition step performed later.

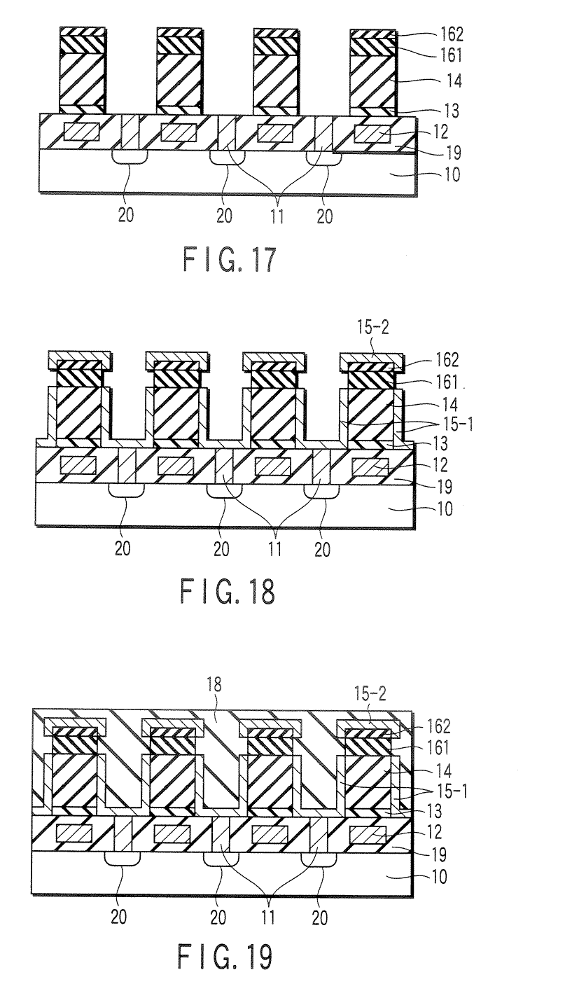

Then, as shown in FIG. 17, a plurality of parallel isolation trenches are formed in the first hard mask 161 and second hard mask 162 by photolithography and reactive ion etching. The remaining first hard mask 161 and second hard mask 162 are used as masks to etch the PZT 14 so as to form a plurality of parallel cell regions.

In this state, as shown in FIG. 17, the PZT 14 and the first hard mask 121 and second hard mask 122 as two types of mask materials are processed to have, e.g., substantially the same width.

After that, as shown in FIG. 18, a noble metal electrode material such as platinum and iridium is deposited by using, e.g., CVD. This electrode material is deposited by a method which well deposits the material even on the sidewalls of the PZT 14. In this step, when two types of mask materials substantially different in electrode material deposition rate are selected as described above, the electrode material is deposited at a normal rate on the sidewalls of the PZT 14 and second hard mask 162 but is not deposited on the sidewalls of the first hard mask 161 at all.

Accordingly, the electrode material is discontinuously deposited to automatically separate the electrode, so electrode layers 15-1 formed on the sidewalls of the PZT 14 can function as electrodes of a parallel-plate capacitor. Finally, a TC parallel ferroelectric memory as shown in FIG. 19 is formed by depositing an interlayer dielectric 18 such as SiO₂ so as to cover the entire surface.

As described above, the ferroelectric storage device fabrication method according to this embodiment also automatically separates the electrode layer. Since this omits the step for separation, the fabrication process can be simplified compared to prior art.

In addition, memory cells can be micropatterned in the ferroelectric storage device according to this embodiment as well, when compared to a device in which the electrode layer is separated by using lithography and etching.

The first to third embodiments of the present invention described above have explained examples in which PZT is selected as the ferroelectric material. However, the present invention is of course also applicable to a device which uses a ferroelectric material other than PZT.

One aspect of the present invention can provide a ferroelectric storage device in which cells are micropatterned by a simple fabrication process, and a method of fabricating the same.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A ferroelectric storage device fabrication method comprising:
forming a ferroelectric layer on a semiconductor substrate;
forming a first hard mask layer on the ferroelectric layer;
forming a second hard mask layer on the first hard mask layer;
forming a plurality of parallel isolation trenches by etching the second hard mask layer, the first hard mask layer, and the ferroelectric layer in a direction perpendicular to a major surface of the substrate; and
forming electrode layers on sidewalls of the ferroelectric layer which face the trenches and an electrode layer on the second hard mask layer.

2. A method according to claim 1, wherein in the etching for forming trenches, the first hard mask layer is side-etched by using an etching rate of the first hard mask layer which is higher than an etching rate of the second hard mask layer and an etching rate of the ferroelectric layer.

3. A method according to claim 1, further comprising, before the formation of the trenches and after the formation of the electrode layers, side-etching the first hard mask layer by using an etching rate of the first hard mask layer which is higher than an etching rate of the second hard mask layer and an etching rate of the ferroelectric layer.

4. A method according to claim 3, wherein the etching for forming trenches is anisotropic etching.

5. A method according to claim 3, wherein the side etching is isotropic etching.

6. A method according to claim 3, wherein the side etching is chemical dry etching.

7. A method according to claim 3, wherein the side etching is wet etching.

8. A method according to claim 1, wherein the etching for forming trenches is reactive ion etching.

9. A method according to claim 1, wherein the ferroelectric layer is made of PZT (lead zirconate titanate).

10. A method according to claim 1, wherein in the formation of electrode layers, the electrode layers are also formed in bottom portions of the trenches.

11. A method according to claim 1, wherein the electrode layers are made of a noble metal.

12. A method according to claim 11, wherein the noble metal is not formed on the first hard mask layer.

13. A method according to claim 11, wherein the noble metal is one of platinum and iridium.

14. A ferroelectric storage device comprising:
a source region and a drain region formed in a semiconductor substrate;
a gate electrode formed on the substrate;
a ferroelectric layer formed on the gate electrode;
a first electrode portion formed on a sidewall of the ferroelectric layer which faces the source region;
a second electrode portion formed on a sidewall of the ferroelectric layer which faces the drain region, and opposing the first electrode portion;
a third electrode portion which connects the first electrode portion to the source region;
a fourth electrode potion which connects the second electrode portion to the drain region;
a first hard mask layer formed on the ferroelectric layer and receding from the sidewalls of the ferroelectric layer;
a second hard mask layer formed on the first hard mask layer; and
a cap electrode layer formed on the second hard mask layer and electrically isolated from the first electrode portion and the second electrode portion.

15. A device according to claim 14, wherein a width in a channel length direction of the first hard mask layer is smaller than a width in the channel length direction of the ferroelectric layer.

16. A device according to claim 15, wherein an etching rate of the first hard mask layer is higher than an etching rate of the second hard mask layer and an etching rate of the ferroelectric layer.

17. A device according to claim 14, wherein the ferroelectric layer is made of PZT (lead zirconate titanate).

18. A device according to claim 14, wherein the first electrode portion, the second electrode portion, the third electrode portion, the fourth electrode potion, and the cap electrode layer are made of a noble metal.

19. A device according to claim 18, wherein the noble metal is not formed on the first hard mask layer.

20. A device according to claim 18, wherein the noble metal is one of platinum and iridium.
